(19) United States
(12) Patent Application Publication
(10) Pub. No.: US 2014/0117335 A1
(43) Pub. Date: May 1, 2014

(54) ORGANIC LIGHT EMITTING DIODE DISPLAY

(71) Applicant: Samsung Display Co., Ltd., Yongin-City (KR)

(72) Inventors: Jung-Woo MOON, Yongin-City (KR); Kie Hyun NAM, Yongin-City (KR)

(73) Assignee: Samsung Display Co., Ltd., Yongin-City (KR)

(21) Appl. No.: 14/046,336

(22) Filed: Oct. 4, 2013

(30) Foreign Application Priority Data
Oct. 26, 2012 (KR) 10-2012-0119737

(51) Int. Cl. H01L 51/52; H01L 27/32

(52) U.S. Cl. CPC H01L 51/5256; H01L 27/32
USPC 257/40; 257/99

(57) ABSTRACT

A display substrate including an organic light emitting member, an encapsulation substrate that is disposed to be opposite to the display substrate, a sealant that is disposed between the display substrate and the encapsulation substrate and bonds the display substrate and the encapsulation substrate, and an outer anti-moisture protective layer that covers the side surface of the sealant are disclosed. In the organic light emitting diode display according to the exemplary embodiment, moisture penetrating into from the outside may be minimized with an outer anti-moisture protective layer by forming a sealant and a getter member in the organic light emitting diode display and forming the outer anti-moisture protective layer on the side surface of the organic light emitting diode display, and moisture penetration resistance may be improved by blocking a small amount of moisture that passes through the outer anti-moisture protective layer and penetrates into with a getter member.

### CROSS-REFERENCE TO RELATED APPLICATIONS

This application claims priority to and the benefit of Korean Patent Application No. 10-2012-0119737 filed in the Korean Intellectual Property Office on Oct. 26, 2012, the entire contents of which are incorporated herein by reference.

### BACKGROUND

1. Field

The described technology relates generally to an organic light emitting diode display.

2. Description of the Related Technology

Generally, an organic light emitting diode display includes a display substrate having an organic light emitting diode, an encapsulation substrate that is disposed to be opposite to the display substrate and protects the organic light emitting diode display of the display substrate, and a sealant that bonds and seals the display substrate and the encapsulation substrate.

When moisture penetrates into an organic light emitting layer, the organic light emitting diode display easily deteriorates, and thus in order to prevent the problem, an organic substrate or metal substrate, which has excellent moisture blocking power, as the encapsulation substrate to prevent moisture from penetrating into the surface thereof and form a getter adjacent to the sealant, thereby blocking moisture that penetrates into the sealant and flows there into.

However, even when the getter is formed, it is difficult for the getter to stand for a long time when the sealant has insufficient moisture penetration resistance, and in order to have high moisture penetration resistance, the width of the sealant needs to be wide, or the amount of the getter needs to be large, and thus there is limitation in decreasing the width of a bezel because an area for enhancing moisture penetration resistance is greatly needed.

Further, when an anti-moisture protective layer is formed on the front surface of an organic light emitting diode display in order to improve moisture penetration resistance in a large organic light emitting diode display, the vulnerable parts are present in most cases due to deterioration in uniformity of the anti-moisture protective layer, the presence of defects, impurities in the chemical vapor deposition (CVD) process and the like, and thus the process difficulty needs to be high. In this case, the manufacturing process costs are increased.

The above information disclosed in this background section is only for enhancement of understanding of the background of the described technology and therefore it may contain information that does not form the prior art that is already known in this country to a person of ordinary skill in the art.

### SUMMARY

The described technology has been made in an effort to provide an organic light emitting diode display having advantages of improved moisture penetration resistance.

An exemplary embodiment provides an organic light emitting diode display including: a display substrate including an organic light emitting member; an encapsulation substrate that is disposed to be opposite to the display substrate; a sealant that is disposed between the display substrate and the encapsulation substrate and bonds the display substrate and the encapsulation substrate; and an outer anti-moisture protective layer that covers the side surface of the sealant.

A getter member that is positioned adjacent to the sealant and blocks outer moisture may be further included.

The outer anti-moisture protective layer may cover the side surface of the encapsulation substrate.

The outer anti-moisture protective layer may be formed along the side surface of the encapsulation substrate, the sealant and the display substrate.

A step difference compensation sealant may be further formed between the sealant and the outer anti-moisture protective layer.

The sealant may be a linear sealant that is formed between the display substrate and a periphery of the encapsulation substrate.

An inner filler that fills an internal space surrounded by the display substrate, the encapsulation substrate and the sealant may be further included.

The sealant may be a surface sealant that fills an internal space between the display substrate and the encapsulation substrate.

An inner anti-moisture protective layer that covers an organic light emitting member of the display substrate may be further included.

The inner anti-moisture protective layer may be formed between the organic light emitting diode and the sealant.

The getter that is dispersed in the sealant may be further included.

The getter may include an organic complex compound that includes aluminum.

The outer anti-moisture protective layer may include an inorganic layer.

The inorganic layer may be any one selected from metal oxide, metal nitride and metal carbide.

The outer anti-moisture protective layer may have a thickness from about 10 nm to about 10 μm.

According to the present embodiments, moisture penetrating into from the outside may be minimized with an outer anti-moisture protective layer by forming a sealant and a getter member in the organic light emitting diode display and forming the outer anti-moisture protective layer on a side surface of the organic light emitting diode display, and moisture penetration resistance may be improved by blocking a small amount of moisture that passes through the outer anti-moisture protective layer and penetrates into with a getter member.

Further, moisture penetration resistance may be improved to reduce the width between a sealant and a getter member, and thus it is possible to reduce a size of the bezel.

In addition, the outer anti-moisture protective layer is formed only on the side surface of the organic light emitting diode display, and thus the uniformity of the outer anti-moisture protective layer is not problematic, thereby reducing the process difficulty to reduce the manufacturing costs thereof, compared to the case where the outer anti-moisture protective layer is formed on the front surface of the organic light emitting diode display.

### BRIEF DESCRIPTION OF THE DRAWINGS

FIG. 1 is a cross-sectional view of an organic light emitting diode display according to a first exemplary embodiment.

FIG. 2 is a view illustrating the arrangement of pixels of the organic light emitting diode display of FIG. 2.

FIG. 3 is a cross-sectional view cut along the line of FIG. 2.

FIG. 4 is a cross-sectional view of an organic light emitting diode display according to a second exemplary embodiment.

FIG. 5 is a cross-sectional view of an organic light emitting diode display according to a third exemplary embodiment.

FIG. 6 is a cross-sectional view of an organic light emitting diode display according to a fourth exemplary embodiment.

FIG. 7 is a cross-sectional view of an organic light emitting diode display according to a fifth exemplary embodiment.

### DETAILED DESCRIPTION

Hereinafter, exemplary embodiments will be described more fully with reference to the accompanying drawings for those skilled in the art to easily implement the present embodiments. As those skilled in the art would realize, the described embodiments may be modified in various different ways, all without departing from the spirit or scope of the present embodiments.

The drawings and description are to be regarded as illustrative in nature and not restrictive. Like reference numerals designate like elements throughout the specification.

Further, the size and thickness of each configuration shown in the drawings are arbitrarily shown for understanding and ease of description, but the present embodiments are not limited thereto.

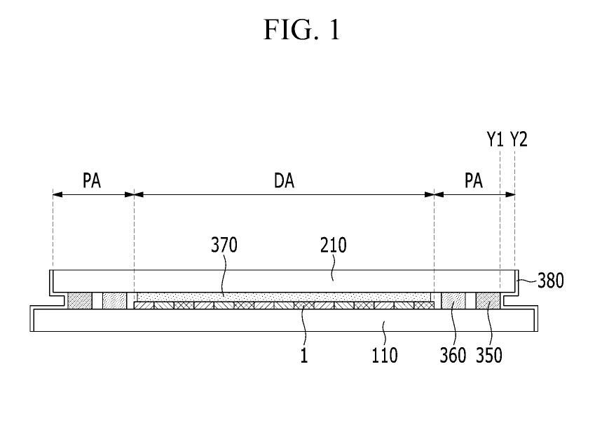

Then, the organic light emitting diode display according to a first exemplary embodiment will be described in detail with reference to FIGS. 1 to 3.

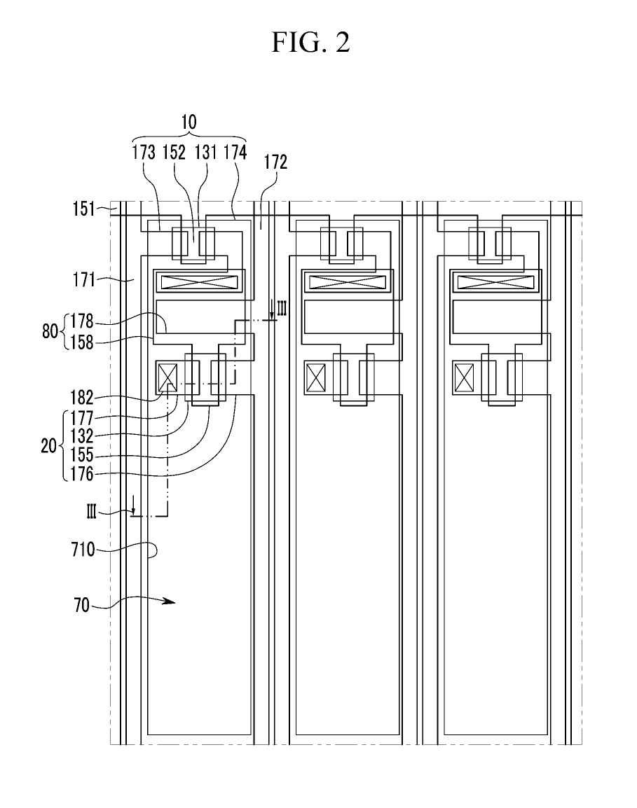

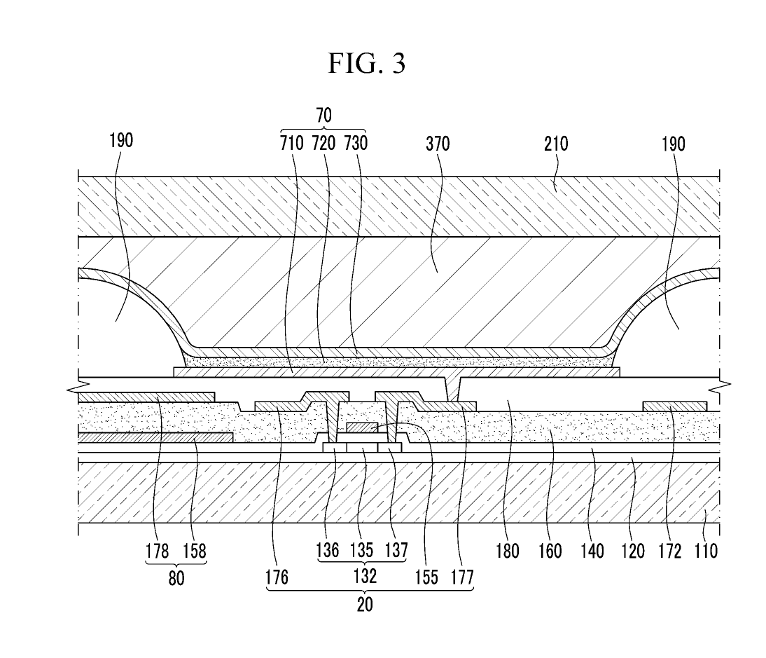

FIG. 1 is a cross-sectional view of an organic light emitting diode display according to a first exemplary embodiment, FIG. 2 is a view illustrating the arrangement of pixels of the organic light emitting diode display of FIG. 2, and FIG. 3 is a cross-sectional view cut along the III-III line of FIG. 2.

As described in FIG. 1, the organic light emitting diode display according to a first exemplary embodiment includes a display substrate 110 including an organic light emitting member 1, an encapsulation substrate 210 that is disposed to be opposite to the display substrate 110, a sealant 350 that is disposed between the display substrate 110 and the encapsulation substrate 210 and bonds the display substrate 110 and the encapsulation substrate 210, a getter member 360 that is positioned adjacent to the sealant 350 and blocks external moisture, and an outer anti-moisture protective layer 380 that covers the side surface of the sealant 350.

The display substrate 110 includes a display area (DA) in which the organic light emitting member 1 is formed and a peripheral area (PA) that is outside the display area (DA). A plurality of pixels is formed in the display area (DA) to display an image.

Hereinafter, the internal structure of an organic light emitting diode display based on pixels formed in the display area (DA) will be first observed with reference to FIGS. 2 and 3.

As illustrated in FIG. 1, the organic light emitting member 1 formed on the display substrate 110 includes a switching thin film transistor 10, a driving thin film transistor 20, an electric storage element 80, and an organic light emitting element 70, which are respectively formed for each pixel. Further, the organic light emitting member 1 further includes a gate line 151 disposed along one direction, a data line 171 insulated from and crossing the gate line 151, and a common power source line 172. Here, each pixel may be defined by a boundary between the gate line 151, the data line 171 and the common power source line 172, but is not limited thereto.

The organic light emitting element 70 includes a first electrode 710, an organic light emitting layer 720 formed on the first electrode 710, and a second electrode 730 formed on the organic light emitting layer 720. Here, the first electrode 710 is an anode that is a hole injection electrode, and the second electrode 730 is a cathode that is an electron injection electrode. A hole and an electron from the first electrode 710 and the second electrode 730, respectively, are injected into the organic light emitting layer 720. When an exciton formed by combination of the injected hole and electron falls from the excited state to the ground state, light emission occurs.

The electric storage element 80 includes a first capacitor plate 158 and a second capacitor plate 178, which are separated by an interlayer insulating layer 160. Here, the interlayer insulating layer 160 becomes a dielectric. The electric capacitance is determined by charge stored in the electric storage element 80 and voltage between both capacitor plates 158 and 178.

The switching thin film transistor 10 includes a switching semiconductor layer 131, a switching gate electrode 152, a switching source electrode 173 and a switching drain electrode 174, and the driving thin film transistor 20 includes a driving semiconductor layer 132, a driving gate electrode 155, a driving source electrode 176 and a driving drain electrode 177.

The switching thin film transistor 10 is used as a switching element that selects a pixel to emit light. The switching gate electrode 152 is connected to the gate line 151. The switching source electrode 173 is connected to the data line 171. The switching drain electrode 174 is disposed spaced apart from the switching source electrode 173 and is connected to the first capacitor plate 158.

The driving thin film transistor 20 applies a driving power source for allowing the organic light emitting layer 720 of the organic light emitting element 70 in a selected pixel to emit light to a first electrode 710. The driving gate electrode 155 is connected to the first capacitor plate 158. The driving source electrode 176 and the second capacitor plate 178 are each connected to the common power source line 172. The driving drain electrode 177 is connected to the first electrode 710 of the organic light emitting element 70 through an electrode contact hole 182.

Through the structure, the switching thin film transistor 10 is driven by a gate voltage applied to the gate line to serve to transfer a data voltage applied to the data line 171 to the driving thin film transistor 20. A voltage corresponding to a difference between a common voltage applied from the common power source line 172 to the driving thin film transistor 20 and a data voltage transferred from the switching thin film transistor 10 is stored in the electric storage element 80, and a current corresponding to the voltage stored in the electric storage element 80 flows into the organic light emitting element 70 through the driving thin film transistor 20 to allow the organic light emitting element 70 to emit light.

Hereinafter, referring to FIG. 3, the structure of the organic light emitting diode display according to the first exemplary embodiment will be described in detail according to the stacking sequence.

The display substrate 110 comprises an insulating substrate composed of glass, quartz, ceramic, plastic and the like. However, the present embodiments are not limited thereto. Therefore, the display substrate 110 may also be formed as a metallic substrate composed of stainless steel and the like.

A buffer layer 120 is formed on the display substrate 110. The buffer layer 120 serves to prevent impure elements from penetrating and planarizing the surface thereof, and may comprise various materials capable of serving the role. As an example, any one of a silicon nitride (SiNx) layer, a silicon oxide (SiO₂) layer and a silicon oxynitride (SiOxNy) layer may be used as the buffer layer 120. However, the buffer layer 120 is not always a necessary configuration and may be omitted according to a kind and process condition of the display substrate 110.

The driving semiconductor layer 132 is formed on the buffer layer 120. The driving semiconductor layer 132 may comprise polysilicon or an oxide semiconductor, and the oxide semiconductor may include one of an oxide based on zinc (Zn), gallium (Ga), tin (Sn) or indium (In), zinc oxide (ZnO), indium-gallium-zinc oxide (InGaZnO₄), indium-zinc oxide (Zn—In—O), or zinc-tin oxide (Zn—Sn—O), which are complex oxides thereof. When the semiconductor layer 131 is composed of an oxide semiconductor, a separate protective layer may be added in order to protect an oxide semiconductor that is vulnerable to the external environment such as high temperature and the like.

Further, the driving semiconductor layer 132 includes a channel area 135 in which impurities are not doped, a source area 136 and a drain area 137, which are p+ doped and formed at both sides of the channel area 135. In this case, the ionic material to be doped is a p-type impurity such as boron (B), and the impurity varies according to a kind of thin film transistor.

A gate insulating layer 140 comprising silicon nitride (SiNx) or silicon oxide (SiO₂) is formed on the driving semiconductor layer 132. A gate wiring including the driving gate electrode 155 is formed on the gate insulating layer 140. Further, the gate wiring further includes the gate line 151, the first capacitor plate 158 and other wirings. In addition, the driving gate electrode 155 is formed to be overlapped with at least a part of the driving semiconductor layer 132, particularly, the channel area 135.

The interlayer insulating layer 160 covering the driving gate electrode 155 is formed on the gate insulating layer 140. The gate insulating layer 140 and the interlayer insulating layer 160 together have through holes exposing the source area 136 and the drain area 137 of the driving semiconductor layer 132. The interlayer insulating layer 160 is prepared by using a ceramic-series material such as silicon nitride (SiNx), silicon oxide (SiO₂) or the like as in the gate insulating layer 140.

A data wiring including the driving source electrode 176 and the driving drain electrode 177 is formed on the interlayer insulating layer 160. Further, the data wiring further includes the data line 171, the common power source line 172, the second capacitor plate and other wirings. In addition, the driving source electrode 176 and the driving drain electrode 177 are each connected to the source area 136 and the drain area 137 through through holes formed on the interlayer insulating layer 160 and the gate insulating layer 140, respectively.

As described above, the driving thin film transistor 20 including the driving semiconductor layer 132, the driving gate electrode 155, the driving source electrode 176 and the driving drain electrode 177 is formed. The configuration of the driving thin film transistor 20 is not limited to the above-described example, and may be variously changed into a known configuration which may be easily performed by those skilled in the art.

A planarization layer 180 covering data wirings 172, 176, 177 and 178 is formed on the interlayer insulating layer 160. The planarization layer 180 serves to eliminate and planarize the step difference in order to increase the light emitting efficiency of the organic light emitting element 70 to be formed thereon. In addition, the planarization layer 180 has an electrode contact hole 182 exposing a part of the drain electrode 177.

The planarization layer 180 may be prepared with one or more materials and the like in acryl-based resins, epoxy resins, phenolic resins, polyamide-based resins, polyimide-based resins, unsaturated polyester-based resins, polyphenylenether-based resins, polyphenylenesulfide-based resins, and benzocyclobutene (BCB).

Further, the first exemplary embodiment according to the present embodiments are not limited to the above-described structure, and one of the planarization layer 180 and the interlayer insulating layer 160 may be omitted in some cases.

The first electrode 710 of the organic light emitting element 70 is formed on the planarization layer 180. That is, the organic light emitting diode display 100 includes a plurality of first electrodes 710 disposed for a plurality of pixels. In this case, the plurality of first electrodes 710 is disposed spaced apart from each other. The first electrode 710 is connected to the drain electrode 177 through the electrode contact hole 182 of the planarization layer 180.

Further, a pixel definition layer 190 exposing the first electrode 710 and having an aperture is formed on the planarization layer 180. That is, the pixel definition layer 190 has a plurality of apertures formed for each pixel. Moreover, the first electrode 710 is disposed to correspond to the aperture of the pixel definition layer 190. However, the first electrode 710 is not disposed only on the aperture of the pixel definition layer 190, and a part of the first electrode 710 may be disposed below the pixel definition layer 190 so as to be overlapped with the pixel definition layer 190. The pixel definition layer 190 may be prepared with a resin such as polyacryl-based resins, polyimide-based resins and the like or a silica-series inorganic material and the like.

An organic light emitting layer 720 is formed on the first electrode 710, and the second electrode 730 is formed on the organic light emitting layer 720. As described above, the organic light emitting diode display 70 including the first electrode 710, the organic light emitting layer 720 and the second electrode 730 is formed.

The organic light emitting layer 720 is composed of a low molecular organic material or a polymer organic material. Further, the organic light emitting layer 720 may be formed as a multi-layer including one or more of a light emitting layer, a hole-injection layer (HIL), a hole-transporting layer (HTL), an electron-transporting layer (ETL) and an electron-injection layer (EIL). When all of them are included, the hole injection layer is disposed on the first electrode 710 that is an anode, and a hole transporting layer, a light emitting layer, an electron transporting layer and an electron injection layer are sequentially stacked thereon.

The organic light emitting layer 720 may include a red organic light emitting layer that emits a red light, a green organic light emitting layer that emits a green light and a blue organic light emitting layer that emits a blue light, and the red organic light emitting layer, the green organic light emitting layer and the blue organic light emitting layer are formed on red pixels, green pixels and blue pixels, respectively, thereby implementing a color image.

Further, the organic light emitting layer 720 together stacks a red organic light emitting layer, a green organic light emitting layer and a blue organic light emitting layer on red pixels, green pixels and blue pixels, and a red color filter, a green color filter and a blue color filter may be formed for each pixel, thereby implementing a color image. As another example, a white organic light emitting layer that emits a white light is formed on all of the red pixels, the green pixels and the blue pixels, and a red color filter, a green color filter and a blue color filter may be formed for each pixel, thereby implementing a color image. When the white organic light emitting layer and the color filter are used to implement a color image, a deposition mask for forming each of the red organic light emitting layer, the green organic light emitting layer, and the blue organic light emitting layer may not be used, and thus is advantageous in improving resolution.

The first electrode 710 and the second electrode 730 may each comprise a transparent conductive material or may comprise a semi-transmissive or reflective conductive material. According to a kind of material that forms the first electrode 710 and the second electrode 730, the organic light emitting diode display according to the first exemplary embodiment may be a front surface emitting type, a rear surface emitting type or a both surface emitting type.

The encapsulation substrate 210 is disposed on the second electrode 730 to be opposite to the display substrate 110. The encapsulation substrate 210 is a substrate that encapsulates at least a display area (DA) in the display substrate on which the organic light emitting element is formed, in the case of a front surface emitting type or a both surface emitting type, the encapsulation substrate 210 comprises a transparent material such as glass, plastic or the like, and in the case of a rear surface emitting type, the encapsulation substrate 210 comprises an opaque material such as metal or the like. The encapsulation substrate 210 has a plate shape.

The sealant 350 is formed between the display substrate 110 and a periphery of the encapsulation substrate 210 and is a linear sealant that is disposed along the display substrate 110 and an edge of the encapsulation substrate 210, and the sealant bonds and seals the display substrate 110 and the encapsulation substrate 210. The sealant 350 is spaced apart at a constant interval from the edge of a surface on which the display substrate 110 and the encapsulation substrate 210 are bonded to be formed in the form of a line.

The sealant 350 includes one selected from epoxy, acrylate, urethane acrylate, and cyanide acrylate. The sealant 350 is applied as a liquid on the display substrate 110 to be UV-cured, thermally cured or naturally cured. The sealant 350 including epoxy, acrylate and urethane acrylate may be UV-cured, the sealant 350 including acrylate may be thermally cured at a temperature less than about 80° C., and the sealant 350 including cyanide acrylate may be naturally cured.

The getter member 360 is spaced apart at a predetermined interval from the sealant 350, and is formed between the peripheral area (PA) of the display substrate 110 and the encapsulation substrate 210. The getter member 360 may be a structure in which inorganic particles of metal such as Mg, Ca, Ba and Mn-series metals, oxide thereof, chloride thereof and the like, and metal oxide are included in an organic binder such as epoxy, acryl, urethane, silicone and the like. Therefore, external moisture is prevented from penetrating into the display area (DA).

An inner filler 370 is formed in an internal space surrounded by the display substrate 110, the encapsulation substrate 210 and the sealant 350. The inner filler 370 serves to protect the organic light emitting member 1 from external moisture, shock and the like.

The outer anti-moisture protective layer 380 is formed along the side surface of the encapsulation substrate 210, the sealant 350 and the display substrate 110, and thus blocks moisture from penetrating into the side surface of the organic light emitting diode display. The outer anti-moisture protective layer 380 is formed by using a film forming device capable of spraying liquid into the side surface of the organic light emitting diode display. Therefore, when the external boundary line Y1 of the sealant 350 is formed at a side that is inner than the external boundary line Y2 of the encapsulation substrate 210, the outer anti-moisture protective layer 380 may be formed even on the bottom surface of the encapsulation substrate that is adjacent to the side surface of the encapsulation substrate 210. The range of forming the outer anti-moisture protective layer 380 may be controlled through the masking, and a pad portion for bonding with a driving chip may be masked such that the outer anti-moisture protective layer 380 is not formed.

The outer anti-moisture protective layer 380 includes an inorganic layer, and includes one selected from metal oxide, metal nitride and metal carbide. The outer anti-moisture protective layer 380 may have a thickness from about 10 nm to about 10 μm. When the thickness of the outer anti-moisture protective layer 380 is smaller than about 10 nm, it is difficult to completely block external moisture, and when the thickness of the outer anti-moisture protective layer 380 is larger than about 10 μm, stress is increased at a boundary surface between the outer anti-moisture protective layer 380 and the encapsulation substrate 210 and between the sealant 350 and the display substrate 110 and it takes long time for the preparation process. When the film quality of the outer anti-moisture protective layer 380 is deteriorated in order to shorten the time for the preparation process, moisture penetration resistance deteriorates.

As described above, moisture penetrating into from the outside may be minimized with the outer anti-moisture protective layer 380 by forming the sealant 350 and a getter member 360 in the organic light emitting diode display and forming the outer anti-moisture protective layer 380 on a side surface of the organic light emitting diode display, and moisture penetration resistance may be improved by blocking a small amount of moisture that passes through the outer anti-moisture protective layer 380 and penetrates into the getter member 360.

Further, moisture penetration resistance may be improved to reduce the width between the sealant 350 and the getter member 360, and thus it is possible to reduce a size of a bezel (or case) which is for casing the organic light emitting diode display.

In addition, the outer anti-moisture protective layer is formed only on the side surface of the organic light emitting diode display, and thus the uniformity of the outer anti-moisture protective layer is not problematic, thereby reducing the process difficulty to reduce the manufacturing costs thereof, compared to the case where the outer anti-moisture protective layer is formed on the front surface of the organic light emitting diode display.

In the first exemplary embodiment, the external boundary line Y1 of the sealant 350 is formed at a side that is inner than the external boundary line Y2 of the encapsulation substrate 210, and thus the outer anti-moisture protective layer 380 is formed to have a step difference at an inner side, but it is also possible to implement the second exemplary embodiment in which a step difference compensation sealant 390 is formed between the sealant 350 and the outer anti-moisture protective layer 380 for the outer anti-moisture protective layer 380 not to have a step difference.

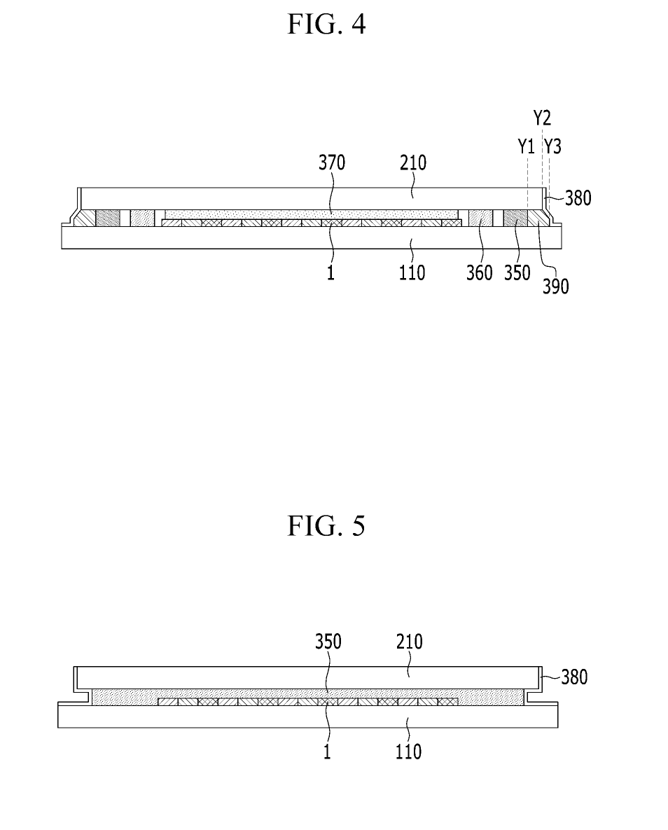

Hereinafter, the second exemplary embodiment will be described in detail with reference to FIG. 4.

FIG. 4 is a cross-sectional view of the organic light emitting diode display according to the second exemplary embodiment.

The second exemplary embodiment illustrated in FIG. 4 is substantially the same as the first exemplary embodiment illustrated in FIGS. 1 to 3, except that the step difference compensation sealant is formed, and thus, the repeated description thereof will be omitted.

As described in FIG. 4, the organic light emitting diode display according to the second exemplary embodiment includes the display substrate 110 including the organic light emitting member 1, the encapsulation substrate 210 that is disposed to be opposite to the display substrate 110, the sealant 350 that is disposed between the display substrate 110 and the encapsulation substrate 210 and bonds the display substrate 110 and the encapsulation substrate 210, the getter member 360 that is positioned adjacent to the sealant 350 and blocks external moisture, and the outer anti-moisture protective layer 380 that covers the side surface of the sealant 350.

The step difference compensation sealant 390 is formed between the sealant 350 and the outer anti-moisture protective layer 380. Therefore, because the external boundary line Y3 of the step difference compensation sealant 390 is formed at a side that is outer than the boundary line Y2 of the encapsulation substrate 210, the outer anti-moisture protective layer 380 does not have a step difference at an inner side, and thus the outer anti-moisture protective layer 380 may be formed uniformly at the side surface of the organic light emitting diode display.

In the first exemplary embodiment, the sealant and the inner filler comprise different materials, but it is possible to implement the third exemplary embodiment in which the sealant is used as an inner filler, it is also possible to implement the fourth exemplary embodiment in which an inner anti-moisture protective layer is formed between the sealant used as the inner filler and the organic light emitting member, and it is also possible to implement the fifth exemplary embodiment in which a getter is distributed in the sealant in the fourth exemplary embodiment.

Hereinafter, the third, fourth and fifth exemplary embodiments will be described in detail with reference to FIGS. 5 to 7.

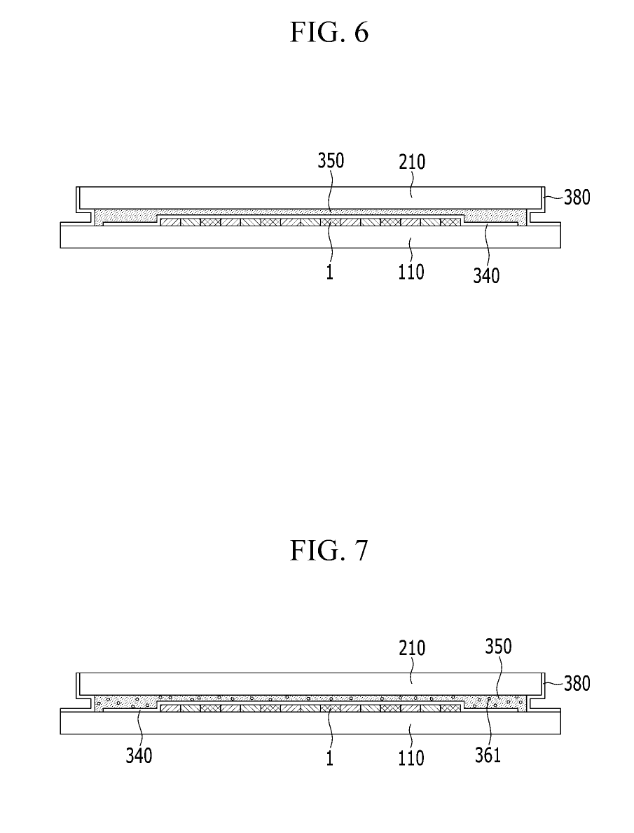

FIG. 5 is a cross-sectional view of an organic light emitting diode display according to the third exemplary embodiment, FIG. 6 is a cross-sectional view of an organic light emitting diode display according to the fourth exemplary embodiment, and FIG. 7 is a cross-sectional view of an organic light emitting diode display according to the fifth exemplary embodiment.

The third to fifth exemplary embodiments illustrated in FIGS. 5 to 7 are substantially the same as the first exemplary embodiment illustrated in FIGS. 1 to 3, except that a sealant is only used as an inner filler, and the repeated description thereof will be omitted.

As described in FIG. 5, the organic light emitting diode display according to the third exemplary embodiment includes the display substrate 110 including the organic light emitting member 1, the encapsulation substrate 210 that is disposed to be opposite to the display substrate 110, the sealant 350 that is disposed between the display substrate 110 and the encapsulation substrate 210 and bonds the display substrate 110 and the encapsulation substrate 210, and the outer anti-moisture protective layer 380 that covers the side surface of the sealant 350. The sealant 350 is a surface sealant that fills the internal space between the display substrate 110 and the encapsulation substrate 210, and thus also serves as the inner filler.

Moisture penetrating into from the outside may be minimized with the outer anti-moisture protective layer 380, and thus a separate getter member is not formed, thereby making it possible to reduce the manufacturing cost thereof and reduce a size of the bezel.

Further, as illustrated in FIG. 6, in the organic light emitting diode display according to the fourth exemplary embodiment, an inner anti-moisture protective layer 340 may be formed on the organic light emitting member 1, and the sealant 350 may be formed on the inner anti-moisture protective layer 340. The inner anti-moisture protective layer 340 may be formed on the second electrode 730 of the organic light emitting diode display 70, and the sealant 350 may be formed on the inner anti-moisture protective layer 340. Therefore, it is possible to block external moisture from penetrating into more perfectly by forming a separate inner anti-moisture protective layer 340.

Further, as illustrated in FIG. 7, in the organic light emitting diode display according to the fifth exemplary embodiment, the inner anti-moisture protective layer 340 may be formed on the second electrode 730 of the organic light emitting member 70, the sealant 350 may be formed on the inner anti-moisture protective layer 340, and a getter 361 may be uniformly distributed in the sealant 350. The getter 361 may include an organic complex compound including aluminum, and inorganic particles such as aluminum-series complexes, CaO or SiO, for example, zeolite, and the like may be an example thereof.

Therefore, a path through which external moisture penetrates into the outer anti-moisture protective layer 380, the sealant 350 including the getter 361 and the inner anti-moisture protective layer 340 may be blocked, and thus external moisture may be blocked from penetrating into more perfectly.

While this disclosure has been described in connection with what is presently considered to be practical exemplary embodiments, it is to be understood that the embodiments are not limited to the disclosed embodiments, but, on the contrary, is intended to cover various modifications and equivalent arrangements included within the spirit and scope of the appended claims.

What is claimed is:

1. An organic light emitting diode display, comprising:
a display substrate comprising an organic light emitting member;
an encapsulation substrate that is disposed opposite to the display substrate;
a sealant that is disposed between the display substrate and the encapsulation substrate and bonds the display substrate and the encapsulation substrate; and
an outer anti-moisture protective layer that covers a side surface of the sealant.

2. The organic light emitting diode display of claim 1, further comprising:
a getter member positioned adjacent to the sealant and configured to block external moisture.

3. The organic light emitting diode display of claim 2, wherein:
the outer anti-moisture protective layer covers a side surface of the encapsulation substrate.

4. The organic light emitting diode display of claim 3, wherein:
the outer anti-moisture protective layer is formed along a side surface of the encapsulation substrate, the sealant and the display substrate.

5. The organic light emitting diode display of claim 2, further comprising:
a step difference compensation sealant that is formed between the sealant and the outer anti-moisture protective layer.

6. The organic light emitting diode display of claim 2, wherein:
the sealant is a linear sealant that is formed between the display substrate and a periphery of the encapsulation substrate.

7. The organic light emitting diode display of claim 6, further comprising:
an inner filler that fills an internal space surrounded by the display substrate, the encapsulation substrate and the sealant.

8. The organic light emitting diode display of claim 1, wherein:
the sealant is a surface sealant that fills an internal space between the display substrate and the encapsulation substrate.

9. The organic light emitting diode display of claim 8, further comprising:
an inner anti-moisture protective layer that covers an organic light emitting member of the display substrate.

10. The organic light emitting diode display of claim 9, wherein:
the inner anti-moisture protective layer is formed between the organic light emitting diode and the sealant.

11. The organic light emitting diode display of claim 10, further comprising:
a getter that is dispersed in the sealant.

12. The organic light emitting diode display of claim 11, wherein:
the getter comprises an organic complex compound that comprises aluminum.

13. The organic light emitting diode display of claim 2, wherein:
the outer anti-moisture protective layer comprises an inorganic layer.

14. The organic light emitting diode display of claim 13, wherein:
the inorganic layer is any one selected from metal oxide, metal nitride and metal carbide.

15. The organic light emitting diode display of claim 2, wherein:
the outer anti-moisture protective layer has a thickness from about 10 nm to about 10 μm.

16. The organic light emitting diode display of claim 2, wherein:
the getter comprises an organic complex compound that comprises aluminum.

17. The organic light emitting diode display of claim 2, wherein:
the getter comprises CaO, SiO or zeolite.

18. The organic light emitting diode display of claim 11, wherein:
the getter comprises CaO, SiO or zeolite.

19. The organic light emitting diode display of claim 1, further comprising a buffer layer.

20. The organic light emitting diode display of claim 19, wherein the buffer layer comprises any one of a silicon nitride (SiNx) layer, a silicon oxide (SiO₂) layer and a silicon oxynitride (SiOxNy) layer.
